(19) United States
(12) Patent Application Publication
(10) Pub. No.: US 2016/0017141 A1
(43) Pub. Date: Jan. 21, 2016

(54) RESIN COMPOSITION FOR PRINTED WIRING BOARD, PREPREG AND METAL-CLAD LAMINATE

(71) Applicant: PANASONIC INTELLECTUAL PROPERTY MANAGEMENT CO., LTD., Osaka (JP)

(72) Inventors: Masaaki MATSUMOTO, Fukushima (JP); Yasunori HOSHINO, Fukushima (JP); Tatsuo YONEMOTO, Fukushima (JP)

(21) Appl. No.: 14/771,487

(22) PCT Filed: Feb. 27, 2014
(86) PCT No.: PCT/JP2014/001069

§ 371 Date: Aug. 28, 2015

(30) Foreign Application Priority Data
Feb. 28, 2013 (JP) 2013-038936
Sep. 30, 2013 (JP) 2013-205077

(51) Int. Cl. C08L 65/00; C08J 5/24; H05K 1/03; C08L 63/00; C08L 33/08

(52) U.S. Cl. CPC C08L 65/00; C08L 63/00; C08L 33/08; H05K 1/0373; C08J 5/24; H05K 2201/0209; H05K 2201/068; C08J 2363/04; C08J 2433/08; C08J 2461/08

(57) ABSTRACT

Provided is a resin composition for a printed wiring board with which a substrate material having a low CTE can be formed while ensuring good moldability. A resin composition for a printed wiring board contains a thermosetting resin including an epoxy resin, a curing agent, an inorganic filler, and an expansion relief component including an acrylic resin that is soluble in an organic solvent. The content of the inorganic filler is 150 parts by mass or more with respect to 100 parts by mass of the total amount of the thermosetting resin and the curing agent. The melt viscosity at 130° C. is less than 50000 Ps.

### TECHNICAL FIELD

The present invention relates to a resin composition for a printed wiring board, a prepreg, and a metal-clad laminate that are used for manufacturing a printed wiring board.

### BACKGROUND ART

Printed wiring boards are widely used in various fields, such as electronic devices, communication devices, and calculators. A necessary number of prepregs are stacked, a metal foil is placed thereon, and laminate-molding is performed thereon to produce a metal-clad laminate, and wire printing is performed on the metal foil of a surface of the metal-clad laminate to form conductive wiring, as a result of which such printed wiring boards are manufactured. The above-described prepreg can be obtained through impregnating a fiber base material such as glass cloth with a resin varnish including a predetermined material, and curing (for example, semi-curing) the impregnated fiber base material.

In recent years, along with rapid development of electronic technology, a reduction in the size and thickness of electronic devices has been achieved, and along with this, there is a demand for a printed wiring board to be excellent in moldability and be less susceptible to warping. In order to suppress the occurrence of warping of a printed wiring board, it is conceivable that it is important to design a substrate material (prepreg or metal-clad laminate) constituting the printed wiring board to have appropriate low thermal expansion properties.

Examples of methods for designing the substrate material to have low thermal expansion properties include a method for forming a prepreg using a resin varnish containing a filler such as silica. In this case, because the CTE (coefficient of thermal expansion) of the prepreg can be reduced, it is possible to suppress thermal expansion. However, a resin varnish that has a high quantity of the filler as described above often has the problem in that good moldability cannot be ensured. For example, in the substrate material, streak unevenness resulting from separation of resin components and the filler may occur, or thin spots may be observed where resin filling is partially missing, leading to the formation of voids, and thus such a resin varnish is not good enough to make the printed wiring board have excellent performance.

On the other hand, a method for forming a prepreg using a resin varnish containing acrylic rubber particles that are insoluble in an organic solvent along with the above-described filler has been proposed (see Patent Document 1, for example). With this method, appropriate flexibility is given to the prepreg after curing of the prepreg, and mechanical strength of the prepreg along with stress relieving effects therein can be increased by the acrylic rubber particles.

### CITATION LIST

Patent Literature

Patent Document 1: JP 2012-39021A

### SUMMARY OF INVENTION

### Technical Problem

However, even with the method disclosed in Patent Document 1 described above, both good moldability and a low CTE have not been achieved, and Patent Document 1 described above does not include studies of related designs. Therefore, Patent Document 1 could not provide a printed wiring board that can be reduced in size and thickness.

The present invention has been made in view of the above-described issues, and an object thereof is to provide a resin composition for a printed wiring board with which good moldability can be ensured and a substrate material having a low CTE can be formed, and to provide a prepreg and a metal-clad laminate that are manufactured using this resin composition for the printed wiring board.

Also, in general, if the content of an inorganic filler increases in a resin composition, the melt viscosity of the resin composition increases, whereas if the content of the inorganic filler decreases, the melt viscosity of the resin composition decreases. In other words, a high quantity of the inorganic filler is effective for the base material to have a low CTE, but the base material has low moldability, and if the resin composition has a low quantity of the inorganic filler, the base material has good moldability, but the base material has a high CTE.

Furthermore, the present invention has been made in view of the above-described issues, and an object thereof is to provide a resin composition for a printed wiring board having a low melt viscosity even if the resin composition contains a large amount of an inorganic filler, and to provide a prepreg and a metal-clad laminate that are manufactured using this resin composition for the printed wiring board.

### Solution to Problem

A resin composition for a printed wiring board according to the present invention contains a thermosetting resin including an epoxy resin, a curing agent, an inorganic filler, and an expansion relief component including an acrylic resin that is soluble in an organic solvent, a content of the inorganic filler being 150 parts by mass or more with respect to 100 parts by mass of the total amount of the thermosetting resin and the curing agent, and a melt viscosity of the resin composition at 130° C. being less than 50000 Ps.

Also, it is preferable that the expansion relief component is an acrylic acid ester copolymer having a weight average molecular weight of 20×10⁴ or more and 90×10⁴ or less.

Also, in the case where the expansion relief component is an acrylic acid ester copolymer having a weight average molecular weight of 70×10⁴ or more and 90×10⁴ or less, it is preferable that a content of the expansion relief component is 5 parts by mass or more and less than 30 parts by mass with respect to 100 parts by mass of the total amount of the thermosetting resin and the curing agent.

Also, it is preferable that the inorganic filler contains silica in an amount of 80% by mass or more.

Also, it is preferable that the curing agent is a bifunctional or polyfunctional phenol resin.

### Advantageous Effects of Invention

A resin composition for a printed wiring board according to the present invention contains an expansion relief component including an acrylic resin, and has a melt viscosity of less than 50000 Ps when heated at 130° C. Accordingly, although the resin composition for the printed wiring board of the present invention contains a large amount of an inorganic filler, good moldability can be ensured and a low CTE of a cured material thereof can be achieved. Therefore, the resin composition serves as a substrate material that prevents occurrence of poor molding and has a low CTE for a prepreg and a metal-clad laminate produced using the resin composition for the printed wiring board. In this manner, with the resin composition for the printed wiring board, a substrate material with which occurrence of warping is suppressed due to a low CTE and good moldability is also ensured can be formed, and therefore a high-performance printed wiring board can be provided.

### DESCRIPTION OF EMBODIMENTS

Hereinafter, embodiments of the present invention will be described.

A resin composition for a printed wiring board contains a thermosetting resin including an epoxy resin, a curing agent, an inorganic filler, and an expansion relief component including an acrylic resin that is soluble in an organic solvent. A prepreg for a printed wiring board can be formed through impregnating a fiber base material with this resin composition for the printed wiring board, and heating and drying the impregnated base material into a semi-cured state (also referred to as a “B-stage state”).

A resin including at least an epoxy resin can be used as the thermosetting resin. The thermosetting resin may be a mixture of the epoxy resin and a thermosetting resin other than the epoxy resin, or may include only the epoxy resin.

There is no particular limitation on the above-described epoxy resin as long as it is used for forming various types of substrate material for a printed wiring board. Specifically, examples of the epoxy resin include naphthalene epoxy resins, cresol novolac epoxy resins, bisphenol A epoxy resins, bisphenol F epoxy resins, bisphenol S epoxy resins, alicyclic epoxy resins, linear aliphatic epoxy resins, cresol novolac epoxy resins, phenol novolac epoxy resins, alkyl phenol novolac epoxy resins, aralkyl epoxy resins, biphenol epoxy resins, dicyclopentadiene epoxy resins, tris(hydroxylphenyl)methane epoxy compounds, epoxidized condensates of a phenol and an aromatic aldehyde having a phenolic hydroxyl group, diglycidyl-etherified bisphenol, diglycidyl-etherified naphthalene diol, glycidyl-etherified phenols, diglycidyl-etherified alcohols, and triglycidyl isocyanurate. Also, in addition to the above examples, various types of glycidyl ether epoxy resins, glycidyl amine epoxy resins, glycidyl ester epoxy resins, oxidized epoxy resins may be used, and phosphorus-modified epoxy resins can be used as well. The epoxy resins may be used alone or in combination. In particular, it is preferable to use an epoxy resin having two or more epoxy groups in one molecule, from the point of view of achieving excellent curability.

In the case where the thermosetting resin includes a thermosetting resin other than the above-described epoxy resins, there is no particular limitation on the type thereof, and examples thereof include polyfunctional cyanate ester resins, polyfunctional maleimide-cyanate ester resins, polyfunctional maleimide resins, unsaturated polyphenylene ether resins, vinyl ester resins, urea resins, diallyl phthalate resins, melanin resins, guanamine resins, unsaturated polyester resins, and melamine-urea co-condensation resins. These thermosetting resins other than the epoxy resins may be used alone or can be used in combination.

A curing agent that has been commonly and conventionally used can be used as the curing agent, and the curing agent can be appropriately selected in accordance with the type of thermosetting resin. Because the thermosetting resin includes the epoxy resin, there is no particular limitation on the curing agent as long as it can be used as the curing agent for the epoxy resin, and examples thereof include diamine-based curing agents such as primary amines and secondary amines, bifunctional or polyfunctional phenol compounds, acid anhydride-based curing agents, dicyandiamide, and polyphenylene ether compounds (PPE). These curing agents may be used alone or in combination.

In particular, bifunctional or polyfunctional phenol resins are preferably used as the curing agent. Examples of such bifunctional or polyfunctional phenol resins include novolac phenol resins, naphthalene phenol resins, cresol novolac resins, aromatic hydrocarbon formaldehyde resin-modified phenol resins, dicyclopentadiene phenol-addition type resins, phenol aralkyl resins, cresol aralkyl resins, naphthol aralkyl resins, biphenyl-modified phenol aralkyl resins, phenol trimethylolmethane resins, tetraphenylolethane resins, naphthol novolac resins, naphthol-phenol co-condensed novolac resins, naphthol-cresol co-condensed novolac resins, biphenyl-modified phenol resins, aminotriazine-modified phenol resins, biphenol, glyoxal tetraphenol resins, bisphenol A novolac resins, and bisphenol F novolac resins. These may be used alone or in combination.

The above-described resin composition for the printed wiring board contains an inorganic filler in a relatively high content ratio in order to reduce the CTE of a cured material thereof. A specific content of the inorganic filler is 150 parts by mass or more with respect to 100 parts by mass of the total amount of the thermosetting resin and the curing agent, and it is preferable that the content is 200 parts by mass or more in order to achieve a further reduction in CTE. As the content of the inorganic filler increases, it can be expected to achieve a reduction in CTE. On the other hand, if the content of the inorganic filler increases, along with a reduction in the percentage of resin components in the resin composition, flowability of a molten resin during hot molding may be affected and moldability may decrease, resulting in issues such as thin spots and resin separation.

Therefore, the amount of the inorganic filler that can be included in the resin composition has a limitation, and it is conceivable that a general upper limit of the inorganic filler is about 400 parts by mass with respect to 100 parts by mass of the resin components when designing resin limited by using the conventional resin composition. In the case of the present invention as well, from the point of view of moldability, the upper limit of the content of the inorganic filler is preferably 400 parts by mass or less, and more preferably 360 parts by mass or less. In this respect, as described later in the present invention, an acrylic resin that is soluble in an organic solvent also has effects of improving moldability, and thus there is the possibility that the resin composition contains the inorganic filler in an amount of up to 450 to 500 parts by mass, which is greater than the 400 parts by mass described above.

There is no particular limitation on the type of inorganic filler described above, and silica, barium sulfate, silicon oxide powder, crushed silica, burned talc, zinc molybdate treated talc, barium titanate, titanium dioxide, clay, alumina, mica, boehmite, zinc borate, zinc stannate, other metal oxides and metal hydrates, aluminum hydroxide, calcium carbonate, magnesium hydroxide, magnesium silicate, short glass fiber, aluminum borate whisker, and silicon carbonate whisker can be used, for example. These may be used alone or in combination. Also, there is no particular limitation on the shape and size of the inorganic filler, and it is possible to use inorganic fillers having different sizes in combination. For the purpose of achieving a high quantity of the inorganic filler, it is preferable to use a nano-order minute filler having a particle size of less than 1 μm in combination with a filler having a particle size of 1 μm or more. Also, a surface treatment can also be performed on these inorganic fillers, using a coupling agent.

It is preferable that the inorganic filler contains silica for the purpose of achieving a reduction in the CTE of a cured material of the resin composition for the printed wiring board and favorably ensuring the other properties of the cured material, such as electrical performance, heat resistance, and heat conductivity. In this case, silica is the predominant component of the inorganic filler by mass, and in particular, 80% by mass or more is preferable.

The resin composition for the printed wiring board contains an acrylic resin that is soluble in an organic solvent as an expansion relief component. The expansion relief component mentioned here refers to a component exhibiting properties of relieving expansion (expansion relief properties) of a cured material of the resin composition when stress resulting from thermal expansion is applied to the cured material thereof. The acrylic resin serving as the expansion relief component is soluble in an organic solvent, and thus unlike acrylic rubber particles or the like, when prepared as a resin varnish along with other resin components in the organic solvent, the acrylic resin dissolves with the other resin components when mixed.

In the present invention, a material that can provide the above-described function to the resin composition can be used as the acrylic resin serving as the expansion relief component, and specific examples thereof include an acrylic acid ester copolymer.

The acrylic acid ester copolymer is a polymer formed of molecules including at least a repeating constitutional unit (acrylic acid ester unit) derived from an acrylic acid ester. The repeating constitutional unit derived from the acrylic acid ester means a repeating constitutional unit formed through polymerization of the acrylic acid ester monomer. The acrylic acid ester copolymer may include the repeating constitutional unit derived from a plurality of different types of acrylic acid esters in the molecule, and may further include a repeating constitutional unit derived from a monomer other than acrylic acid ester. Alternatively, the acrylic acid ester copolymer may consist of the repeating constitutional unit derived from the plurality of different types of acrylic acid esters in the molecule. Also, the acrylic acid ester copolymer may be a copolymer including a repeating constitutional unit derived from one type of acrylic acid ester and a repeating constitutional unit derived from a monomer other than acrylic acid ester.

In the above-described acrylic acid ester, examples of a substituent directly bound to carbon in an ester bond include alkyl groups and substituted alkyl groups (specifically, substituted alkyl group in which any of hydrogen atoms of the alkyl group is substituted by another functional group). The alkyl group may be linear, branched, or alicyclic. In addition, the above-described substituent may be an aromatic. Specific examples of the acrylic acid ester include methyl acrylate, ethyl acrylate, propyl acrylate, isopropyl acrylate, butyl acrylate, isobutyl acrylate, t-butyl acrylate, pentyl acrylate, hexyl acrylate, cyclohexyl acrylate, octyl acrylate, decyl acrylate, lauryl acrylate, and benzyl acrylate, but are not limited thereto.

An example of the monomer other than the above-described acrylic acid esters is acrylonitrile. Also, in addition to this, examples thereof include vinyl-based monomers other than acrylic acid esters, such as acrylamide, acrylic acid, methacrylic acid, methacrylic acid esters, styrene, ethylene, propylene, and butadiene. The acrylic acid ester copolymer may include a repeating constitutional unit derived from two or more different types of monomers other than the acrylic acid esters.

The repeating constitutional unit constituting the acrylic acid ester copolymers may be arranged randomly (in other words, may be a random copolymer), or may be a block copolymer, which is constituted by blocks for the same type of repeating constitutional unit. Also, the acrylic acid ester copolymer may be a branched graft copolymer or a crosslinked polymer that has branches or crosslinks to the extent that the effects of the present invention are not inhibited.

The acrylic acid ester copolymer can be obtained through radical polymerization of a predetermined monomer, for example, and there is no limitation to such a manufacture method.

The acrylic acid ester copolymer further has a functional group on a terminal, a side chain, or a main chain of the polymer molecule. In particular, the functional group that reacts with at least one of the epoxy resin and the curing agent is preferable. Examples of such functional groups include epoxy groups, a hydroxyl group, a carboxyl group, amino groups, and amide groups. As a result of the functional group being bound to the acrylic acid ester copolymer, the functional group can react with components included in the resin composition for the printed wiring board and is thus integrated into the structure of a curing system of the thermosetting resin, as a result of which it can be expected to achieve improvement in heat resistance, compatibility, and chemical resistance. Among the functional groups mentioned above, the epoxy group is particularly preferable. One polymer molecule may have a plurality of functional groups. Note that having the functional group described above also refers to being modified by the functional group described above, and having the epoxy groups also refers to “epoxy modified”, for example.

In particular, it is preferable that the acrylic acid ester copolymer has a molecular structure having rubber elasticity, and in this case, effects of the expansion relief properties can be further increased. For example, the acrylic acid ester copolymer including a repeating constitutional unit derived from butyl acrylate and a repeating constitutional unit derived from acrylonitrile has rubber elasticity. Also, in addition, when the acrylic acid ester copolymer includes a repeating constitutional unit derived from butadiene, the acrylic acid ester copolymer has rubber elasticity.

When the expansion relief component including the acrylic resin, which is soluble in an organic solvent, is mixed with the other components of the resin composition for the printed wiring board in the organic solvent and a resin varnish is prepared, the expansion relief component is homogeneously mixed with the other resin components that are soluble in a solvent. A solid acrylic resin may be dissolved in a solvent when varnish is prepared to be used, or a liquid acrylic resin dissolved in an organic solvent in advance may be used. Thus, it is conceivable that the acrylic resin is dissolved in the solvent and homogeneously mixed with the other resin components, and thus the expansion relief component is likely to exhibit the above-described expansion relief properties and separation of the resin components from the filler is likely to be suppressed in a flow state during hot molding. Examples of the organic solvent include ketone solvents such as acetone, methyl ethyl ketone, and cyclohexanone, aromatic solvents such as toluene and xylene, and ester solvents such as ethyl acetate, and these may be used alone or in combination.

The resin composition for the printed wiring board contains the expansion relief component including the acrylic resin, and thus the viscosity of the resin composition for the printed wiring board is likely to be appropriately controlled. Thus, in a substrate material (prepreg or metal-clad laminate) formed using the resin composition for the printed wiring board, separation of the resin components derived from the resin composition for the printed wiring board from the inorganic filler is unlikely to occur, and thus the base material has a good moldability. Also, the resin composition for the printed wiring board contains the expansion relief component, and thus the CTE of the prepreg can be reduced. This is because that thermal expansion is suppressed by the expansion relief component due to the above-described expansion relief properties of the expansion relief component. In particular, if the expansion relief component including the acrylic resin is the above-described acrylic acid ester copolymer, the moldability can be further increased, and also a low CTE can be easily achieved.

There is no particular limitation on the molecular weight of the acrylic acid ester copolymer, and from the point of view of balance regarding the solubility of the acrylic acid ester copolymer in the organic solvent, its expansion relieving function, and easiness of the adjustment of the melt viscosity of the resin composition, it is preferable that a weight average molecular weight (Mw) is 10×10⁴ or more and 90×10⁴ or less. If the weight average molecular weight (Mw) is in the above-described range, the above-described expansion relief properties are likely to be exhibited, and good moldability during hot molding is likely to be ensured. More preferably, the weight average molecular weight (Mw) is 10×10⁴ or more and 50×10⁴ or less. In this manner, if the acrylic acid ester copolymer having a low molecular weight is used, even if the resin composition contains a large amount of the inorganic filler, the melt viscosity of the resin composition can be reduced compared to a case where the acrylic acid ester copolymer having a high molecular weight, which exceeds 50×10⁴, is used. Note that the weight average molecular weight mentioned here refers to a value in terms of polystyrene measured by gel permeation chromatography, for example.

The resin composition for the printed wiring board may contain other components as required as well as the above-described thermosetting resin, curing agent, inorganic filler, and expansion relief component as long as effects of the present invention are not inhibited. Solvents for dilution, curing accelerators such as imidazole, antioxidants, wetting and dispersing agents and coupling agents for improving the miscibility of the inorganic filler, photostabilizers, viscosity modifiers, flame retardants, coloring agents, and antifoaming agents may be blended as the other components, for example. Ketone solvents such as acetone, methyl ethyl ketone, and cyclohexanone, aromatic solvents such as toluene and xylene, and nitrogen-containing solvents such as dimethylformamide can be used as the solvent for dilution, for example.

The resin composition for the printed wiring board can be prepared through blending the thermosetting resin including the epoxy resin, curing agent, inorganic filler, expansion relief component, and other components that are appropriately added as required, such as an additive agent, in an organic solvent.

It is necessary that the resin composition for the printed wiring board has a melt viscosity of less than 50000 Ps at 130° C. (1 Ps=0.1 Pa·s). In other words, the resin composition for the printed wiring board contains an inorganic filler in a high content and the acrylic resin, and thereby has both a low CTE and good moldability. Moreover, in order to realize both properties at the same time, it is important for the melt viscosity to be less than 50000 Ps.

Specifically, as described above, in general, there is a trade-off relationship in which as the content of an inorganic filler in a resin composition increases, the CTE of a cured material decreases, but the moldability during hot molding deteriorates. Therefore, there is a limit to achieving both a low CTE and moldability only by using an inorganic filler as a means for reducing CTE. In contrast, in the present invention, as a result of the resin composition containing the inorganic filler and the acrylic resin, a further reduction in CTE is realized due to these synergistic effects while good moldability is realized even in the case where the resin composition contains an inorganic filler in a high content of 150 parts by mass or more. However, it was found that as a result of the resin composition containing the acrylic resin, the melt viscosity of the resin composition has a tendency to increase, and if the melt viscosity is very high, the moldability is adversely affected. Regarding this point, as a result of repeating experiments and trial and error, the inventors of this application have found the following points. Specifically, they found that even in the case where an inorganic filler in a high content and the acrylic resin are mixed as components of the resin composition, if the melt viscosity at 130° C. is less than 50000 Ps, it is possible to achieve both a further reduction in CTE and good moldability.

Incidentally, it is conceivable that an increase in the melt viscosity is affected by not only the content of the acrylic resin but also the molecular weight of an acrylic resin that is used, or the amount of an inorganic filler mixed in the resin composition. Therefore, although there is no particular limitation on the content of the acrylic resin, if an acrylic acid ester copolymer having a weight average molecular weight (Mw) of 70×10⁴ to 90×10⁴, which is relatively high, is used, for example, in order to suppress an excessive increase in the melt viscosity of the resin composition and realize a reduction in CTE and good moldability, it is preferable that the content of the acrylic resin is 5 parts by mass or more and less than 30 parts by mass with respect to 100 parts by mass of the total amount of the thermosetting resin and the curing agent.

Although measurement of the melt viscosity of a resin composition for a printed wiring board will be described in examples that will be described later, note that a measurement sample for measuring melt viscosity can be obtained through impregnating a fiber base material with the resin composition for the printed wiring board and semi-curing the resin composition, and peeling a cured material in this semi-cured state therefrom. If the melt viscosity at 130° C. exceeds 50000 Ps, the moldability of a prepreg deteriorates, resulting in issues such as thin spots, for example. More preferably, the melt viscosity at 130° C. is 45000 Ps or less.

On the other hand, there is no particular limitation on a lower limit of the melt viscosity at 130° C. as long as an appropriate resin flowability is ensured when the prepreg is hot molded, and a good insulating layer can be formed in a metal-clad laminate. For example, in the case where the resin composition contains an inorganic filler in an amount of 150 parts by mass or more with respect to 100 parts by mass of the resin components, it is conceivable that the lower limit of the melt viscosity is 10000 Ps or more.

The prepreg can be formed through impregnating a fiber base material with the resin composition for the printed wiring board, and heating and drying the impregnated resin composition to a semi-cured state (B-stage state). A temperature condition and time period in which the semi-cured state is achieved can be set to 120 to 190° C. and 3 to 15 minutes, for example.

There is no particular limitation on the fiber base material, and a base material that is woven such that the warp and weft intersect substantially orthogonally, such as plain weave, can be used. For example, woven cloth of inorganic fiber such as glass cloth, and a fiber base material made of organic fiber such as aramid cloth and polyester cloth can be used. Although there is no particular limitation on the thickness of a fiber base material, it is preferable that the thickness thereof is 10 to 200 μm.

A metal foil is placed on each side or one side of the prepreg or a stack of a plurality of the prepregs, and the obtained laminate is hot-press molded to produce an integrated laminate, as a result of which a metal-clad laminate can be produced. A copper foil can be used as the metal foil, for example. The above-described laminate-molding can be performed by heating and pressing using a multistage vacuum press, double belt press, or the like.

The prepreg or metal-clad laminate formed in this manner is formed using the resin composition for the printed wiring board, and thus as described above, the prepreg or metal-clad laminate has a low CTE and good moldability. Therefore, such a prepreg is unlikely to warp, and separation of the resin components from the inorganic filler (resin separation) and thin spots are also unlikely to occur, and thus such a prepreg can be used effectively as a substrate material for producing a high-performance printed wiring board.

The printed wiring board is formed through providing a conductive pattern on the above-described metal-clad laminate. The conductive pattern can be formed by a subtractive method, for example. Also, thereafter, a package such as FBGA (Fine pitch Ball Grid Array) can be manufactured through mounting a semiconductor device on the above-described printed wiring board and sealing the semiconductor device. Also, by using such a package as a sub-package, a package such as PoP (Package on Package) can also be manufactured through laminating a plurality of the sub-packages.

The printed wiring board formed in this manner is constituted by a substrate material having a low CTE, and thus warping is unlikely to occur, as a result of which it can be said that the substrate material is more compatible with thin or small electronic devices. Thus, this substrate material can be used for the printed wiring board formed in this manner, in various applications such as communication and measuring devices, OA devices, and its peripheral terminals.

### EXAMPLE

Hereinafter, the present invention will be specifically described using Examples.

### Examples 1 to 6 and Comparative Examples 1 to 5

A thermosetting resin, curing agent, inorganic filler, expansion relief component including an acrylic resin, and additive agent (dispersing agent and coupling agent), which are shown below, were prepared, and these raw materials were mixed based on the composition (parts by mass) shown in Table 1 to prepare a resin varnish (a resin composition for a printed wiring board). Details of the raw materials are as follows.

Thermosetting Resin

Polyfunctional epoxy resin (“EPPN-502H” available from Nippon Kayaku Co., Ltd.)

Curing Agent

Naphthalene skeleton phenol resin (“HPC-9500” available from DIC Corporation)

Phenol novolac resin (“TD2090” available from DIC Corporation)

Note that each of the above-described two types of curing agent is a bifunctional or polyfunctional phenol resin.

Expansion Relief Component including Acrylic Resin

Acrylic acid ester copolymer (epoxy modified-acrylic resin, “SG-P3” available from Nagase ChemteX Corporation, Mw: 85×10⁴)

Acrylic acid ester copolymer (epoxy modified-acrylic resin, “SG-P3mw1” available from Nagase ChemteX Corporation, Mw: 25×10⁴)

Inorganic Filler

Silica A (“SC-4500SQ” available from Admatechs Company Limited)

Silica B (“SC-2500SEJ” available from Admatechs Company Limited)

Magnesium hydroxide (“MGZ-6R” available from Sakai Chemical Industry Co., Ltd.)

Additive Agent

Dispersing agent (“W903” available from BYK Japan K.K.)

Coupling agent (“KBE-9007” available from Shin-Etsu Chemical Co., Ltd.)

Glass Cloth (“2117” available from Nitto Boseki Co., Ltd., thickness: 95 μm) serving as a fiber base material was impregnated with the resin varnish prepared in the blend composition shown in Table 1 so that the thickness of glass cloth after curing was 100 μm, and the impregnated glass cloth was heated and dried at 145° C. for 2 minutes until reaching a semi-cured state, as a result of which a prepreg was manufactured.

Four prepregs described above were stacked, a copper foil (thickness of 12 μm), as a type of metal foil, was laminated on each side thereof, and the laminated prepreg was molded through heating at 200° C. for 120 minutes while pressing at 6.0 MPa under vacuum conditions, as a result of which a copper-clad laminate was manufactured as a metal-clad laminate.

Various types of physical properties (melt viscosity, thin spots, resin separation, and CTE) were evaluated using the prepregs or copper-clad laminates of the examples and comparative examples that were obtained in this manner. Table 1 also shows results of the evaluation of physical properties of the examples and comparative examples.

Note that various types of physical properties were evaluated using methods shown below.

Melt Viscosity Measurement

Resin powder was separated from a glass cloth base material through crumpling the prepreg obtained in the examples and comparative examples. The resin powder was pressed to form a pellet, and the melt viscosity of the pellet was measured through measuring viscosity at a temperature of 130° C. under conditions where pressure was 0.49 to 3.9 MPa (5 to 40 kg/cm²), using a “Koka type flow tester (CFT-100)” available from SHIMADZU CORPORATION, with a nozzle having a dimension of 0.5 mmφ.

Thin Spot Evaluation

The copper foil of the surface of the copper-clad laminate obtained in the examples and comparative examples was removed therefrom through etching, the formation of thin spots on the surface was visually observed, and a determination of “OK” was made for no thin spot formation and “NG” for thin spot formation.

Resin Separation Evaluation

The copper foil of the surface of the copper-clad laminate obtained in the examples and comparative examples was removed through etching, occurrence of streak unevenness on the surface and the like was visually observed to check whether resin separation occurred, and a determination of “OK” was made for no resin separation and “streak NG” for having resin separation.

CTE (Tension)

The copper foil of the surface of the copper-clad laminate obtained in the examples and comparative examples was removed through etching to prepare a sample for evaluation, and the thermal expansion coefficient in the longitudinal direction of the sample for evaluation was measured at a temperature of less than a glass transition temperature of a cured material of resin in an insulating layer. Measurement was performed conforming to a TMA method (Thermo-mechanical analysis) in accordance with JIS C 6481, and a Thermo-Mechanical Analyzer (“TMA/SS6000” available from Seiko Instruments Inc.) was used for measurement.

TABLE 1

| Blending condition and physical | | | | | | | | | |
|---|---|---|---|---|---|---|---|---|---|
| property evaluation | | | | | | | | | |
| | Product | Raw material | | | | | | | |
| | name | name | Unit | Ex. 1 | Ex. 2 | Ex. 3 | Ex. 4 | Ex. 5 | Ex. 6 |
| Thermosetting | EPPN-502H | polyfunctional | parts by | 58 | 58 | 58 | 58 | 58 | 58 |
| resin | | epoxy resin | mass | | | | | | |
| Curing agent | HPC-9500 | naphthalene | parts by | 21 | 21 | 21 | 21 | 21 | 21 |
| | | skeleton | mass | | | | | | |
| | | phenol resin | | | | | | | |
| | TD-2090 | phenol | parts by | 21 | 21 | 21 | 21 | 21 | 21 |
| | | novolac resin | mass | | | | | | |
| Expansion | SG-P3 | acrylic acid | parts by | 10 | 20 | 30 | 0 | 0 | 10 |
| relief | | ester | mass | | | | | | |
| component | | copolymer | | | | | | | |
| (acrylic resin) | | Mw: 85 × 10⁴ | | | | | | | |
| | SG-P3mw1 | acrylic acid | parts by | 0 | 0 | 0 | 10 | 30 | 0 |
| | | ester | mass | | | | | | |
| | | copolymer | | | | | | | |
| | | Mw: 25 × 10⁴ | | | | | | | |
| Inorganic filler | SC-4500SQ | silica A | parts by | 184 | 184 | 0 | 184 | 184 | 258 |
| | | | mass | | | | | | |
| | SC-2500SEJ | silica B | parts by | 46 | 46 | 170 | 46 | 46 | 91 |
| | | | mass | | | | | | |
| | MGZ-6R | magnesium | parts by | 30 | 30 | 30 | 30 | 30 | 0 |
| | | hydroxide | mass | | | | | | |
| Additive agent | W903 | dispersing | phr | 0.4 | 0.4 | 0.4 | 0.4 | 0.4 | 0.4 |
| | | agent | | | | | | | |
| | KBE-9007 | coupling | phr | 2.3 | 2.3 | 0 | 2.3 | 2.3 | 2.3 |
| | | agent | | | | | | | |

| | | | | | | | |
|---|---|---|---|---|---|---|---|
| Total amount of inorganic filler | parts by | 260 | 260 | 200 | 260 | 260 | 350 |
| (numerical value in parentheses is content of | mass | (88.5) | (88.5) | (81.5) | (88.5) | (88.5) | (100) |
| silica [%]) | | | | | | | |
| Melt viscosity | Ps | 30000 | 40000 | 45000 | 20000 | 25000 | 40000 |
| Thin spot | — | OK | OK | OK | OK | OK | OK |
| Resin separation | — | OK | OK | OK | OK | OK | OK |
| CTE (Tension) | ppm/° C. | 7.5 | 7.0 | 7.5 | 7.5 | 6.5 | 6.0 |

| Blending condition and physical | | | | | | | | |
|---|---|---|---|---|---|---|---|---|
| property evaluation | | | | | | | | |
| | Product | Raw material | | Comp. | Comp. | Comp. | Comp. | Comp. |
| | name | name | Unit | Ex. 1 | Ex. 2 | Ex. 3 | Ex. 4 | Ex. 5 |
| Thermosetting | EPPN-502H | polyfunctional | parts by | 58 | 58 | 58 | 58 | 58 |
| resin | | epoxy resin | mass | | | | | |
| Curing agent | HPC-9500 | naphthalene | parts by | 21 | 21 | 21 | 21 | 21 |
| | | skeleton | mass | | | | | |
| | | phenol resin | | | | | | |
| | TD-2090 | phenol | parts by | 21 | 21 | 21 | 21 | 21 |
| | | novolac resin | mass | | | | | |
| Expansion | SG-P3 | acrylic acid | parts by | 30 | 0 | 0 | 0 | 0 |
| relief | | ester | mass | | | | | |
| component | | copolymer | | | | | | |
| (acrylic resin) | | Mw: 85 × 10⁴ | | | | | | |
| | SG-P3mw1 | acrylic acid | parts by | 0 | 0 | 0 | 0 | 0 |
| | | ester | mass | | | | | |
| | | copolymer | | | | | | |
| | | Mw: 25 × 10⁴ | | | | | | |
| Inorganic filler | SC-4500SQ | silica A | parts by | 184 | 0 | 0 | 184 | 259 |
| | | | mass | | | | | |
| | SC-2500SEJ | silica B | parts by | 46 | 105 | 170 | 46 | 91 |
| | | | mass | | | | | |
| | MGZ-6R | magnesium | parts by | 30 | 30 | 30 | 30 | 0 |
| | | hydroxide | mass | | | | | |
| Additive agent | W903 | dispersing | phr | 0.4 | 0 | 0 | 0.4 | 0.4 |
| | | agent | | | | | | |
| | KBE-9007 | coupling | phr | 2.3 | 0 | 0 | 2.3 | 2.3 |
| | | agent | | | | | | |

| | | | | | | |
|---|---|---|---|---|---|---|
| Total amount of inorganic filler | parts by | 260 | 135 | 200 | 260 | 350 |
| (numerical value in parentheses is content of | mass | (88.5) | (55.6) | (81.5) | (88.5) | (100) |
| silica [%]) | | | | | | |
| Melt viscosity | Ps | 50000 | 10000 | 15000 | 17000 | 20000 |
| Thin spot | — | NG | OK | OK | OK | NG |
| Resin separation | — | OK | OK | streak NG | streak NG | streak NG |
| CTE (Tension) | ppm/° C. | 6.5 | 10.0 | 9.0 | 8.5 | 7.0 |

Examples 1 to 6 had a low CTE, and thin spots and resin separation were not observed, and thus it could be found that Examples 1 to 6 had excellent moldability.

In particular, comparing Example 1 and Example 4, having the same composition except for the expansion relief component, it was confirmed that the melt viscosity of the resin composition could be further reduced in a case where an acrylic acid ester copolymer having a low molecular weight was used than in a case where an acrylic acid ester copolymer having a high molecular weight was used.

Also, it was confirmed that in spite of a high content of the inorganic filler, the melt viscosity of the resin composition in Example 5 in which an acrylic acid ester copolymer having a low molecular weight was used could be more significantly reduced than that in Example 3 in which an acrylic acid ester copolymer having a high molecular weight was used.

Also, comparing Example 1 and Example 6, having the same composition except for the inorganic filler, it was confirmed that if the amount of the inorganic filler was increased from 260 parts by mass to 350 parts by mass, the CTE decreased and the melt viscosity of the resin composition increased to about 40000 Ps at most.

Also, comparing Example 1 and Example 2, it was confirmed that if the amount of the acrylic acid ester copolymer having a high molecular weight was increased from 10 parts by mass to 20 parts by mass, the CTE further decreased and the melt viscosity of the resin composition increased to about 40000 Ps at most. Effects similar to this were significant in a case where the acrylic acid ester copolymer having a low molecular weight was used. In other words, comparing Example 4 and Example 5, it was confirmed that if the amount of the acrylic acid ester copolymer having a low molecular weight was increased from 10 parts by mass to 30 parts by mass, the CTE further decreased and the melt viscosity of the resin composition increased from 20000 Ps to about 25000 Ps at most.

On the other hand, in Comparative Example 1, a reduction in CTE was achieved, but thin spots were observed due to a high melt viscosity and moldability deteriorated. Also, it was confirmed that as a result of reducing the amount of the inorganic filler in Comparative Example 2, moldability was good, but the CTE increased. Because Comparative Examples 3 to 5 did not include the expansion relief component including the acrylic resin, and thus resin separation occurred and a reduction in moldability was recognized.

As described above, the prepreg and metal-clad laminate were formed using the resin composition for the printed wiring board of the present invention in Examples 1 to 6, and thus it could be found that Examples 1 to 6 had excellent moldability while maintaining a low CTE. Therefore, warping was also unlikely to occur, and a high-performance printed wiring board could be produced.

1. A resin composition for a printed wiring board, comprising:
a thermosetting resin including an epoxy resin;
a curing agent;
an inorganic filler; and
an expansion relief component including an acrylic resin that is soluble in an organic solvent,
a content of the inorganic filler being 150 parts by mass or more with respect to 100 parts by mass of the total amount of the thermosetting resin and the curing agent, and
a melt viscosity of the resin composition at 130° C. being less than 50000 Ps.

2. The resin composition for the printed wiring board according to claim 1, wherein
the expansion relief component is an acrylic acid ester copolymer having a weight average molecular weight of 10×10⁴ or more and 90×10⁴ or less.

3. The resin composition for the printed wiring board according to claim 2, wherein
the expansion relief component is an acrylic acid ester copolymer having a weight average molecular weight of 70×10⁴ or more and 90×10⁴ or less, and
a content of the expansion relief component is 5 parts by mass or more and less than 30 parts by mass with respect to 100 parts by mass of the total amount of the thermosetting resin and the curing agent.

4. The resin composition for the printed wiring board according to claim 1, wherein
the expansion relief component is an acrylic acid ester copolymer having a weight average molecular weight of 10×10⁴ or more and 50×10⁴ or less.

5. The resin composition for the printed wiring board according to claim 2, wherein
the acrylic acid ester copolymer has a functional group that reacts with at least one of the epoxy resin and the curing agent.

6. The resin composition for the printed wiring board according to claim 1, wherein
the inorganic filler contains silica in an amount of 80% by mass or more.

7. The resin composition for the printed wiring board according to claim 1, wherein
the curing agent is a bifunctional or polyfunctional phenol resin.

8. A prepreg formed through impregnating a fiber base material with the resin composition for the printed wiring board according to claim 1.

9. A metal-clad laminate formed through laminating the prepreg according to claim 8 with a metal foil, and hot-press molding the laminated prepreg.
